(19) United States
(12) Patent Application Publication
(10) Pub. No.: US 2009/0090616 A1
(43) Pub. Date: Apr. 9, 2009

(54) SYSTEM AND METHOD FOR PLASMA ENHANCED THIN FILM DEPOSITION

(75) Inventors: CHEN-CHUNG DU, Hsinchu (TW); JEN-RONG HUANG, Hsinchu (TW); MUH-WANG LIANG, Miaoli County (TW); CHIH-CHEN CHANG, Taipei County (TW); SHENG-LANG LEE, Hsinchu County (TW); CHING-HUEI WU, Hsinchu (TW); CHAN-HSING LO, Hsinchu County (TW)

Correspondence Address: WPAT, PC, 7225 BEVERLY ST., ANNANDALE, VA, 22003, US

(73) Assignee: INDUSTRIAL TECHNOLOGY RESEARCH INSTITUTE, Hsin-Chu (TW)

(21) Appl. No.: 12/015,999

(22) Filed: Jan. 17, 2008

(30) Foreign Application Priority Data
Oct. 5, 2007 (TW) 096137384

(51) Int. Cl. C23C 14/32

(52) U.S. Cl. 204/192.13; 204/298.03

(57) ABSTRACT

A system and a method for plasma enhanced thin film deposition are disclosed, in which the system comprises a plasma enhanced thin film deposition apparatus and a plasma process monitoring device. The plasma enhanced thin film deposition apparatus receives pulsed power and a reactive gas, whereby plasma discharging occurs to ionize the reactive gas into a plurality of radicals for thin film deposition. The plasma process monitoring device comprises an optical emission spectroscopy (OES) and a pulsed plasma modulation device, in which the OES detects spectrum intensities of the radicals and the pulsed plasma modulation device calculates a spectrum intensity ratio of the radicals so as to modulate the plasma duty time of pulsed power, thereby high deposition rate as well as real-time monitoring on thin film deposition quality can be achieved.

### BACKGROUND OF THE INVENTION

1. Field of the Invention

The present invention generally relates to a system and a method for plasma enhanced thin film deposition and, more particularly, to a system and a method for plasma enhanced thin film deposition, using an optical emission spectroscopy (OES) detecting spectrum intensities of the radicals and a pulsed plasma modulation device calculating a spectrum intensity ratio of the radicals so as to modulate pulsed plasma parameters, thereby high deposition rate as well as real-time monitoring on thin film deposition quality can be achieved.

2. Description of the Prior Art

The microcrystalline silicon (μc-Si) thin film is used in tandem Si-based thin film solar cells with high photoelectric conversion efficiency. Conventionally, the microcrystalline silicon thin film is grown by plasma enhanced chemical vapor deposition (PECVD) with low deposition rate and non-uniform crystallinity, which results in issues such as low throughput and low crystallinity. In particular, there is need in improving the deposition rate and crystallinity quality because the thickness of the microcrystalline silicon thin film is required to be 1˜2 μm for the silicon thin film solar cells.

The conventional PECVD uses high-frequency pulsed power to reduce powders formed by polymerization of radicals generated by continuous high-frequency power that may lead to formation of amorphous silicon thin films.

In JP 20030421313 “Manufacturing method for silicon thin film solar cells”, the pulsed plasma duty time ratio Pr=T_{ON}/T_{ON}+T_{OFF} in different deposition time intervals is pre-determined, as shown in FIG. 1. During the initial time interval T1, the pulsed plasma duty time ratio Pr1 is so small that the initial layer is grown at a low deposition rate. Then, during the time interval T2, the pulsed plasma duty time ratio Pr2 is higher to obtain a microcrystalline silicon thin film at a high deposition rate, which can be used in manufacture of high-efficiency silicon solar cells.

However, during microcrystalline silicon deposition, the actual ionization rates of SiH₄ and H₂ by plasma dynamically affect the deposition rate and the crystallinity of the microcrystalline silicon thin film. JP 20030421313 uses different pulsed plasma duty time ratios Pr in different deposition time intervals to stepwisely control the ionization rates of SiH₄ and H₂ to improve the deposition rate and thin film uniformity of the microcrystalline silicon thin film. However, JP 20030421313 does not provide real-time monitoring and quantitative analysis for the ionized gas during thin film deposition. In FIG. 1, only two steps of process time T and pulsed plasma duty time ratio Pr are shown; however, in practical cases, the pulsed plasma duty time ratio Pr is required to be divided into multiple steps with pre-determined conditions for multi-step processing to achieve optimal deposition rate, which leads to complicated processing. Moreover, JP 20030421313 discloses an open-loop system, in which the ionization rate of the reactive gas is unstable due to gas flow and deposition on electrodes during long thin film deposition time in a mass-production manner, which affects the effects of pre-determined conditions and results in thin film quality not as good as expected.

### SUMMARY OF THE INVENTION

It is an object of the present invention to provide to a system and a method for plasma enhanced thin film deposition, capable of providing real-time monitoring and analysis on the radical spectrum for calculation on spectrum intensity ratio to modulate the pulse power parameters to obtain a high-quality microcrystalline silicon thin film by preventing amorphous silicon from growing at a high deposition rate.

In order to achieve the foregoing object, the present invention provides a system for plasma enhanced thin film deposition, the system comprising:
a plasma enhanced thin film deposition apparatus, capable of receiving pulsed power and a reactive gas, whereby plasma discharging occurs to ionize the reactive gas into a plurality of radicals for thin film deposition; and
a plasma process monitoring device, comprising:
   an optical emission spectroscopy, capable of detecting spectrum intensities of the radicals; and
   a pulsed plasma modulation device, being connected to the optical emission spectroscopy and the pulsed power to calculate a spectrum intensity ratio of the radicals and thereby modulate pulsed plasma parameters.

It is preferable that the plasma enhanced thin film deposition apparatus is a plasma enhanced chemical vapor-phase deposition apparatus.

It is preferable that the plurality of radicals comprise hydrogen radicals (H*) and silane radicals (SiH*).

It is preferable that the reactive gas comprises hydrogen (H₂) and silane (SiH₄).

It is preferable that the pulsed plasma parameters comprise the pulsed plasma duty time.

It is preferable that the pulsed plasma parameters comprise the pulsed plasma power.

In order to achieve the foregoing object, the present invention provides a method for plasma enhanced thin film deposition, the method comprising steps of:
providing a plasma enhanced thin film deposition apparatus, capable of receiving pulsed power and a reactive gas, whereby plasma discharging occurs to ionize the reactive gas into a plurality of radicals for thin film deposition; and
providing a plasma process monitoring device, capable of detecting spectrum intensities of the radicals and calculating a spectrum intensity ratio r of the radicals to modulate pulsed plasma parameters.

It is preferable that a crystallization transition value R defined as a spectrum intensity ratio of the radicals (SiH*/H*)_{Transition} when amorphous silicon starts to grow during thin film deposition is compared to the spectrum intensity ratio r=(SiH*/H*)_{Process} detected by the plasma process monitoring device, the crystallization transition value R being a criterion for determining whether a deposited thin film is a microcrystalline silicon thin film.

It is preferable that the pulsed plasma modulation device shortens the pulsed plasma duty time to avoid the formation of amorphous silicon if the spectrum intensity ratio r is larger than the crystallization transition value R, otherwise the pulsed plasma modulation device lengthens the pulsed plasma duty time to achieve high deposition rate if the spectrum intensity ratio r is smaller than the crystallization transition value R.

It is preferable that the plasma process monitoring device provides a pulsed plasma modulation procedure to modulate the pulsed power and the pulsed plasma duty time.

It is preferable that the pulsed plasma modulation device modulates the pulsed plasma duty time according to an equation expressed as:

tₙ₊₁=tₙ+k*tₙ*(R−r)/R

wherein
n indicates an integer equal to or larger than zero;
tₙ₊₁ indicates the next pulsed plasma duty time;
tₙ indicates the current pulsed plasma duty time;
k indicates a characteristic weighting factor;
R indicates the crystallization transition ratio; and
r indicates the spectrum intensity ratio of the radicals during the deposition process.

### BRIEF DESCRIPTION OF THE DRAWINGS

The objects, spirits and advantages of the preferred embodiment of the present invention will be readily understood by the accompanying drawings and detailed descriptions, wherein:

FIG. 1 shows the relation of the pulsed plasma duty time ratio Pr and deposition time T according to JP 20030421313;

FIG. 2 is a schematic diagram showing a system for plasma enhanced thin film deposition according to the present invention;

FIG. 3 is a sketch map showing the spectrum of the radicals detected by an optical emission spectroscopy during the growth of a microcrystalline silicon thin film;

FIG. 4 is a sketch map showing the modulation process to deposit a microcrystalline silicon thin film by modulating the pulsed plasma duty time according to the present invention; and

FIG. 5 is a flow-chart of the method according to the present invention.

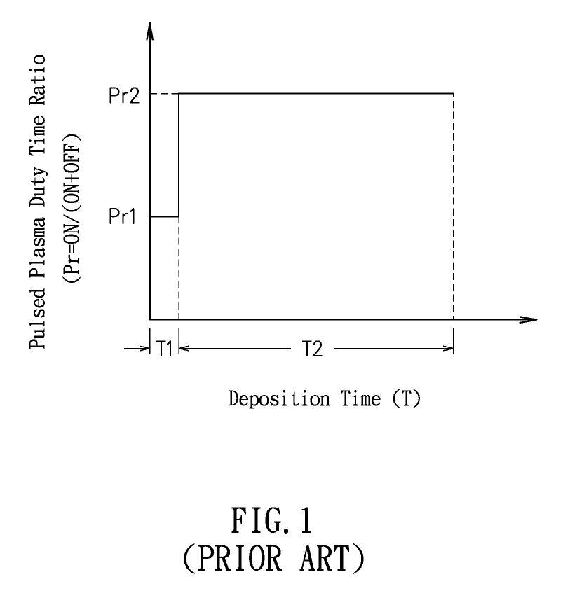

### DETAILED DESCRIPTION OF THE PREFERRED EMBODIMENT

The present invention can be exemplified but not limited by the preferred embodiment as described hereinafter.

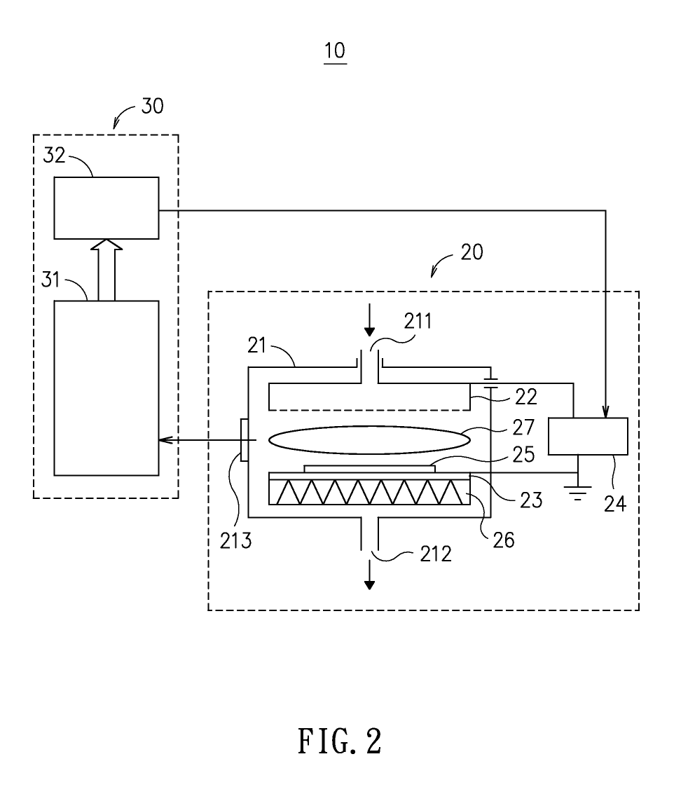

Please refer to FIG. 2, which is schematic diagram showing a system for plasma enhanced thin film deposition according to the present invention. The plasma enhanced thin film deposition system 10 comprises a plasma enhanced thin film deposition apparatus 20 and a plasma process monitoring device 30.

In FIG. 2, the plasma enhanced thin film deposition apparatus 20 is a plasma enhanced chemical vapor-phase deposition (PECVD) apparatus, comprising: a chamber 21, having a reactive gas inlet 211 and a gas outlet 212. Inside the chamber 21, there is installed a top electrode 22 and a bottom electrode 23. The top electrode 22 is coupled to one terminal of a pulsed power supply 24. The bottom electrode 23 is capable of carrying a substrate 25 whereon a thin film deposits so that the substrate 25 is interposed between the top electrode 22 and the bottom electrode 23. A heater 26 is installed under the bottom electrode 23. Meanwhile, the chamber 21 and the bottom electrode 23 are coupled to another terminal of the pulsed power supply 24. A gas supply (not shown) provides a reactive gas for thin film deposition comprising, for example, hydrogen H₂ and silane SiH₄ through the reactive gas inlet 211 into the chamber 21. The pulsed power supply 24 provides the chamber 21 with pulsed power so as to cause plasma discharge 27 by ionizing the reactive gas into hydrogen radicals (H*) and silane radicals (SiH*) between the top electrode 22 and the bottom electrode 23. The heater 26 heats up the substrate 25 to the temperature required for thin film deposition on the substrate 25. During thin film deposition, the reacted gas in the chamber 21 are exhausted through the gas outlet 212 which is connected to a vacuum pump (not shown).

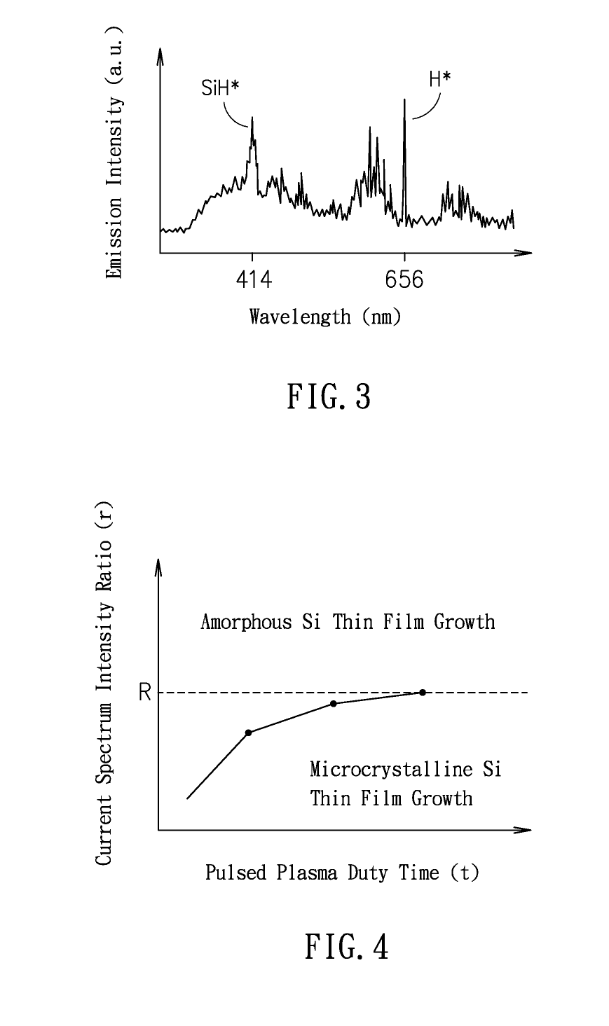

The present invention is characterized in that the plasma process monitoring device 30 comprises an optical emission spectroscopy 31 and a pulsed plasma modulation device 32. The optical emission spectroscopy 31 detects the spectrum of the radicals. The pulsed plasma modulation device 32 is coupled to the optical emission spectroscopy 31 and the pulsed power supply 24. A spectrum intensity ratio r of the radicals can be calculated based on the spectrum intensities of the radicals analyzed by the optical emission spectroscopy 31 so as to modulate the pulsed power parameters such as the pulsed plasma duty time and the pulsed power. Referring to the spectrum in FIG. 3, the microcrystalline silicon thin film deposition rate and thin film crystallinity are influenced mainly by the spectrum intensities for silane radicals (SiH*) and hydrogen radicals (H*) that are represented by two peak values at a wavelength of 414 nm and at a wavelength of 656 nm, respectively.

It is well-known by the persons with skills in thin film deposition that the deposition rate of the microcrystalline silicon thin film gets higher with more amorphous silicon when the spectrum intensity for silane radicals (SiH*) is stronger; on the contrary, better microcrystalline silicon thin film can be achieved with lowered deposition rate when the spectrum intensity for hydrogen radicals (H*) is stronger.

A crystallization transition value R defined as a spectrum intensity ratio of the radicals (SiH*/H*)_{Transition} when amorphous silicon starts to grow during thin film deposition is compared to the spectrum intensity ratio r=(SiH*/H*)_{Process} detected by the plasma process monitoring device. The crystallization transition value R is a criterion for determining whether a deposited thin film is a microcrystalline silicon thin film.

When the detected spectrum intensity ratio r is larger than the crystallization transition value R, it is easy to form amorphous silicon because there are powders formed on the substrate surface by polymerization of silane radicals (SiH*) in spite of high deposition rate.

Therefore, a high-quality microcrystalline silicon thin film can be obtained at a high deposition rate by controlling the spectrum intensity ratio r of the radicals during thin film deposition to be close to but smaller than the crystallization transition value R.

The plasma process monitoring device 30 according to the present invention uses the optical emission spectroscopy 31 to perform real-time monitoring on the spectrum intensities of silane radicals (SiH*) and hydrogen radicals (H*) during thin film deposition and the pulsed plasma modulation device 32 to calculate the spectrum intensity ratio r of the radicals to modulate the pulsed power parameters and control the deposition rate and crystallinity of the thin film. As mentioned previously, the pulsed power parameters comprise the pulsed plasma duty time and the power. The plasma process monitoring device provides a pulsed plasma modulation procedure to modulate the pulsed plasma duty time (t) (in FIG. 4) according to an equation expressed as:

tₙ₊₁=tₙ+k*tₙ*(R−r)/R

wherein
n indicates an integer equal to or larger than zero;
tₙ₊₁ indicates the next pulsed plasma duty time;
tₙ indicates the current pulsed plasma duty time;
k indicates a characteristic correction factor;
R indicates the crystallization transition ratio; and
r indicates the spectrum intensity ratio of the radicals.

The characteristic correction factor k is larger than zero, which varies based on the kind of plasma. When n=0, t₀ is an initial value for the pulsed plasma duty time as thin film deposition starts.

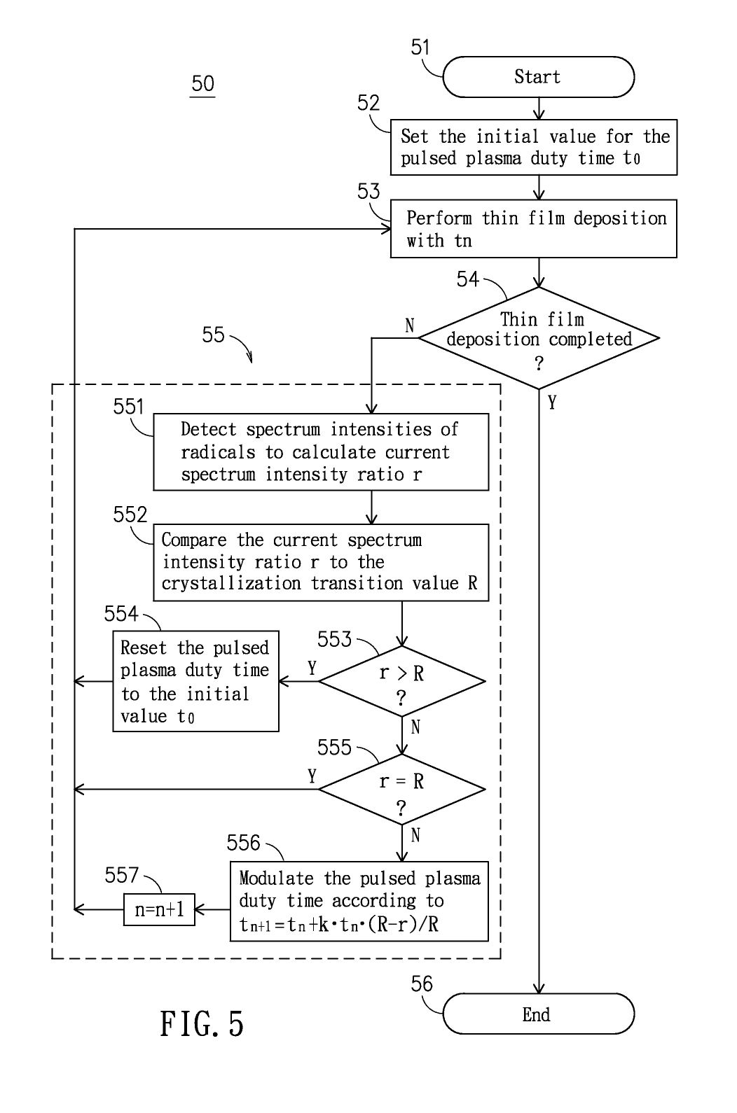

Please refer to FIG. 5 for a flow-chart 50 of the method for plasma enhanced thin film deposition according to the present invention. The flow-chart 50 comprises steps described hereinafter.

In Step 51, thin film deposition starts.

In Step 52, the initial value t₀ for the pulsed plasma duty time of pulsed power is shortened according to actual operational experiences. In this step, the deposition rate is low but the grown thin film is assured to be microcrystalline silicon thin film.

In Step 53, thin film deposition is performed with modulated pulsed plasma duty time tₙ.

In Step 54, it is determined whether thin film deposition is completed.

If thin film deposition is completed, the method goes to Step 56 to end the thin film deposition process; otherwise, a plasma monitoring step (Step 55) is performed to modulate the pulsed plasma duty time. The plasma monitoring step 55 comprises steps described hereinafter.

In Step 551, spectrum intensities of the radicals are detected to calculate the current spectrum intensity ratio r.

In Step 552, the current spectrum intensity ratio r is compared to the crystallization transition value R.

In Step 553, it is determined whether the current spectrum intensity ratio r is larger than the crystallization transition value R.

During deposition, if the current spectrum intensity ratio r is larger than the crystallization transition value R, it indicates that amorphous silicon has grown and the pulsed plasma duty time is too long. The pulsed plasma duty time has to be reset to the initial value t₀ in Step 554 to assure that the grown thin film is microcrystalline silicon. The Step 554 is performed by the pulsed plasma modulation device 32, as shown in FIG. 2. Otherwise, the method goes to Step 555 if the current spectrum intensity ratio r is not larger than the crystallization transition value R.

In Step 555, it is determined whether the current spectrum intensity ratio r is equal to the crystallization transition value R.

If the current spectrum intensity ratio r is equal to the crystallization transition value R, it indicates that the grown thin film is microcrystalline silicon and the deposition rate is at a maximum level. Therefore, the pulsed plasma duty time is remained unchanged and the method returns to Step 53 for thin film deposition.

If the current spectrum intensity ratio r is smaller than the crystallization transition value R, it indicates that the grown thin film is microcrystalline silicon and the deposition rate is low. Therefore, in Step 556, the pulsed plasma duty time is modulated to be longer in order to increase the deposition rate according to tn+1=tn+k*tn*(R−r)/R. Then, the method returns to Step 53 for thin film deposition.

Therefore, by monitoring the spectrum intensity ratio of the radicals to modulate the pulsed plasma duty time such that r=R, the microcrystalline silicon thin film can be grown at a highest deposition rate until thin film deposition ends. (In Step 56)

According to the above discussion, it is apparent that the present invention discloses a system and a method for plasma enhanced thin film deposition, characterized in that plasma process monitoring device is used to monitor the spectrum intensities of the radicals and calculate the spectrum intensity ratio of the radicals to modulate pulsed plasma duty time so that high-crystallinity microcrystalline silicon can be obtained at a highest deposition rate. Moreover, the power of the pulsed power can also be modulated according to a pulsed plasma modulation procedure. In the present invention, the system for plasma enhanced thin film deposition is a closed-loop system using an optical emission spectroscopy to detect ionization variation due to gas flow, deposition on electrode surface and to quantitatively calculate the spectrum intensity ratio r so as to achieve real-time modulation on the pulsed power parameters such as the pulsed plasma duty time and the pulsed power. The present invention is advantageous in stabilized microcrystalline silicon thin film deposition. Compared to the prior art, which uses multi-step processing with preset conditions to achieve optimal deposition rate, the present invention simplifies the process by modulating the pulsed power parameters according to the radical ratio to obtain a high-crystallinity microcrystalline silicon thin film at a highest deposition rate. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A system for plasma enhanced thin film deposition, the system comprising:
a plasma enhanced thin film deposition apparatus, capable of receiving pulsed power and a reactive gas, whereby plasma discharging occurs to ionize the reactive gas into a plurality of radicals for thin film deposition; and
a plasma process monitoring device, comprising:
an optical emission spectroscopy, capable of detecting spectrum intensities of the radicals; and
a pulsed plasma modulation device, being connected to the optical emission spectroscopy and the pulsed power to calculate a spectrum intensity ratio of the radicals and thereby modulate pulsed plasma parameters.

2. The system as recited in claim 1, wherein the plasma enhanced thin film deposition apparatus is a plasma enhanced chemical vapor-phase deposition apparatus.

3. The system as recited in claim 1, wherein the plurality of radicals comprise hydrogen radicals (H*) and silane radicals (SiH*).

4. The system as recited in claim 3, wherein the reactive gas comprises hydrogen (H₂) and silane (SiH₄).

5. The system as recited in claim 1, wherein the pulsed plasma parameters comprise the pulsed plasma duty time.

6. The system as recited in claim 1, wherein the pulsed plasma parameters comprise the pulsed plasma power.

7. A method for plasma enhanced thin film deposition, the method comprising steps of:
providing a plasma enhanced thin film deposition apparatus, capable of receiving pulsed power and a reactive gas, whereby plasma discharging occurs to ionize the reactive gas into a plurality of radicals for thin film deposition; and
providing a plasma process monitoring device, capable of detecting spectrum intensities of the radicals and calculating a spectrum intensity ratio r of the radicals to modulate pulsed plasma parameters.

8. The method as recited in claim 7, wherein the plasma process monitoring device comprises:
an optical emission spectroscopy, capable of detecting spectrum intensities of the radicals; and
a pulsed plasma modulation device, being connected to the optical emission spectroscopy and the pulsed power to calculate the spectrum intensity ratio r of the radicals and thereby modulate the pulsed plasma parameters.

9. The method as recited in claim 7, wherein the plurality of radicals comprise hydrogen radicals (H*) and silane radicals (SiH*).

10. The method as recited in claim 9, wherein the reactive gas comprises hydrogen (H₂) and silane (SiH₄).

11. The method as recited in claim 9, wherein a crystallization transition value R defined as a spectrum intensity ratio of the radicals (SiH*/H*)_{Transition} when amorphous silicon starts to grow during thin film deposition is compared to the spectrum intensity ratio r=(SiH*/H*)_{Process} detected by the plasma process monitoring device, the crystallization transition value R being a criterion for determining whether a deposited thin film is a microcrystalline silicon thin film.

12. The method as recited in claim 11, wherein the pulsed plasma modulation device shortens the pulsed plasma duty time to avoid the formation of amorphous silicon if the spectrum intensity ratio r is larger than the crystallization transition value R, otherwise the pulsed plasma modulation device lengthens the pulsed plasma duty time to achieve high deposition rate if the spectrum intensity ratio r is smaller than the crystallization transition value R.

13. The method as recited in claim 8, wherein the plasma process monitoring device provides a pulsed plasma modulation procedure to modulate the pulsed power and the pulsed plasma duty time.

14. The method as recited in claim 12, wherein the pulsed plasma modulation device modulates the pulsed plasma duty time according to an equation expressed as:
tₙ₊₁=tₙ+k*tₙ*(R−r)/R
wherein
n indicates an integer equal to or larger than zero;
tₙ₊₁ indicates the next pulsed plasma duty time;
tₙ indicates the current pulsed plasma duty time;
k indicates a characteristic correction factor;
R indicates the crystallization transition ratio; and
r indicates the spectrum intensity ratio of the radicals.
